(19) United States
(12) Patent Application Publication
(10) Pub. No.: US 2026/0182392 A1
(43) Pub. Date: Jun. 25, 2026

(54) METHOD OF SEMICONDUCTOR MANUFACTURING, CORRESPONDING SEMICONDUCTOR PRODUCT AND DEVICE

(71) Applicant: STMicroelectronics International N.V., Geneva (CH)

(72) Inventors: Dario VITELLO, Merate (LC) (IT); Claudio ZAFFERONI, Milano (IT); Antonio BELLIZZI, Cologno Monzese (IT); Federico LEONE, Lodi (IT)

(73) Assignee: STMicroelectronics International N.V., Geneva (CH)

(21) Appl. No.: 19/425,294

(22) Filed: Dec. 18, 2025

(30) Foreign Application Priority Data
Dec. 24, 2024 (IT) 102024000029988

(51) Int. Cl. H10W 70/09; H10W 70/652; H10W 70/66; H10W 74/01

(52) U.S. Cl. CPC H10W 70/09; H10W 70/6528; H10W 74/014; H10W 70/66

(57) ABSTRACT

Semiconductor dice are encapsulated in an electrically insulating encapsulation to form a panel. A seed layer is formed on the panel. A redistribution layer common to the semiconductor dice is formed by growing electrically conductive material onto first regions of the seed layer. Second regions of the seed layer, adjacent and complementary to the first regions, are covered by a mask blocking the growing of electrically conductive material. Solder pads are grown on the redistribution layer and electrically coupled to semiconductor dice. The mask and second regions of the seed layer are subsequently removed. The solder pads are grown by: keeping the redistribution layer at a plating electric potential via the second regions, and electrolytically growing solder material on the redistribution layer kept at the plating electric potential via the second regions of the seed layer.

### PRIORITY CLAIM

This application claims the priority benefit of Italian Application for Patent No. 102024000029988 filed on Dec. 24, 2024, the content of which is hereby incorporated by reference in its entirety to the maximum extent allowable by law.

### TECHNICAL FIELD

The description relates to semiconductor devices.

One or more embodiments can be applied to processes for manufacturing (integrated circuit (IC)) semiconductor devices processed via panel level processing.

### BACKGROUND

Finished semiconductor devices may be configured to be mounted on a supporting substrate (a printed circuit board (PCB), for instance) via soldering, for instance.

To that effect, final processing steps in conventional manufacturing processes of semiconductor devices comprise providing solderable material at the outer pads (that is, the pads configured to be soldered on the PCB) to facilitate mounting on the final substrate.

In leadframe based semiconductor devices, for instance, solderable material (tin, for instance) may be grown via an electrolytic plating bath where an electric field between an anode and the pads to be plated (acting as a cathode) forces positively charged metal ions to move to the cathode where they give up their charge and deposit themselves as metal on the surface of the pads.

In manufacturing processes such as so-called panel level packaging (PLP), the plating step is performed via an electroless plating bath, since an electric field cannot be established between the anode and the pads of the devices.

However, electroless plating of tin material results in the formation of a relatively thin layer of tin at the pads, which gives unsatisfactory results in terms of solderability.

Electroless-Nickel Immersion-Gold (ENIG), an electroless plating process, gives satisfactory results. However, plating gold significantly increases the cost of the package.

Reference is made to United States Patent Application Publication Nos. 2022/0084931 A1, 2011/0189848 A1, 2023/0326866 A1, 2024/0063145 A1, and 2023/0178507 A1 and Chinese Patent No. CN 113594052 B, all of which are incorporated herein, to provide background information in the related technological area.

There is a need in the art to overcome the drawbacks discussed in the foregoing.

### SUMMARY

One or more embodiments also relate to a method.

One or more embodiments also relate to a corresponding (intermediate) semiconductor product and a corresponding semiconductor device.

Solutions as described herein may be applied to panel level processing in manufacturing processes of semiconductor devices.

Solutions as described herein facilitate providing a semiconductor device processed via panel level processing with pads of solder material.

Solutions as described herein involve electroplating solder material to form pads of solder material configured to be soldered on a final supporting substrate.

In solutions as described herein, a side surface of the pads of solder material is exposed at the side surface of the semiconductor device thus providing wettable flanks for the semiconductor device.

In an embodiment, a method comprises: encapsulating a plurality of semiconductor dice in an electrically insulating encapsulation to form a panel having the plurality of semiconductor dice embedded therein; forming a seed layer of seed material at a surface of said panel; forming an electrically conductive redistribution layer common to the plurality of semiconductor dice embedded in the panel by growing electrically conductive material onto first regions of the seed layer formed at the surface of the panel, wherein the seed layer comprises second regions adjacent and complementary to said first regions of the seed layer having electrically conductive material grown thereon; growing pads of solder material onto said common redistribution layer, wherein the pads of solder material are electrically coupled to semiconductor dice in the plurality of semiconductor dice via the common redistribution layer; and removing the seed material at said second regions of the seed layer. The step of growing pads of solder material onto said common redistribution layer comprises: keeping the common redistribution layer at a plating electric potential via said second regions of the seed layer; and electrolytically growing solder material onto the common redistribution layer kept at the plating electric potential via said second regions of the seed layer.

In an embodiment, a semiconductor product comprises: a panel of electrically insulating encapsulation material having a plurality of semiconductor dice embedded therein; a seed layer of seed material formed at a surface of said panel; a redistribution layer common to the plurality of semiconductor dice embedded in the panel formed by electrically conductive material grown onto first regions of said seed layer formed at the surface of the panel; and pads of solder material electrolytically grown onto said common redistribution layer, wherein the pads of solder material are electrically coupled to semiconductor dice in the plurality of semiconductor dice via the common redistribution layer, wherein electrolytically growing the pads of solder material is facilitated by keeping the common redistribution layer at a plating electric potential via second regions of the seed layer adjacent and complementary to said first regions of the seed layer having electrically conductive material grown thereon, the seed material at said second regions of the seed layer being subsequently removed.

### BRIEF DESCRIPTION OF THE DRAWINGS

One or more embodiments will now be described, by way of example only, with reference to the annexed figures, wherein:

FIGS. 1A to 1K are cross-sectional views illustrative of a sequence of processing steps, and

FIGS. 2 to 6 are plan views illustrative of details of a semiconductor product resulting from certain processing steps of the sequence illustrated in FIGS. 1A to 1L,

FIGS. 7 and 8 are a cross-sectional view and a side view (in the direction of view indicated by the arrow VIII of FIG. 7) of a semiconductor device obtainable via processing steps, and

FIGS. 9A to 9F are cross-sectional views illustrative of a sequence of processing steps.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

As mentioned, (finished) semiconductor devices may be configured to be mounted on a final supporting substrate such as a printed circuit board (PCB), for instance.

Attaching a semiconductor device to such a substrate may be done via soldering, for instance, in order to facilitate forming electrical coupling between the semiconductor device and the PCB.

To that effect, solder material is provided at the pads configured to be soldered onto the substrate.

In leadframe based semiconductor devices, solder material (tin or a tin alloy, for instance) may be provided via electrolytic (or galvanic) plating; a layer of solder material may be formed at the pads via electrolytic plating, facilitated by an electric field established between an anode and the pads to be plated (acting as a cathode) that forces positively charged metal ions to move to the cathode where they give up their charge and deposit themselves as metal at the surface of the pads.

In manufacturing processes such as in so-called panel level packaging (PLP), pads are formed by selectively growing electrically conductive material at a surface of a panel. Pads formed in this way are not electrically coupled to each other making difficult to establish an electric field for electrolytic plating, and an electroless plating is used for plating solder material at the surface of the pads.

However, only a relatively thin (for instance, about 3 microns) layer of solder material such as tin may be grown via electroless plating, which gives unsatisfactory results in terms of solderability.

Electroless-Nickel Immersion-Gold (ENIG), an electroless plating process, is thus used, which gives satisfactory results. However, plating gold significantly increases the cost of the package.

Solutions as described herein may be applied to panel level processing in manufacturing processes of semiconductor devices.

Solutions as described herein facilitate providing a semiconductor device processed via panel level processing with pads of solder material.

Solutions as described herein involve electroplating solder material to form pads of solder material configured to be soldered on a final supporting substrate.

In solutions as described herein, a side surface of the pads of solder material is exposed at the side surface of the semiconductor device thus providing wettable flanks for the semiconductor device.

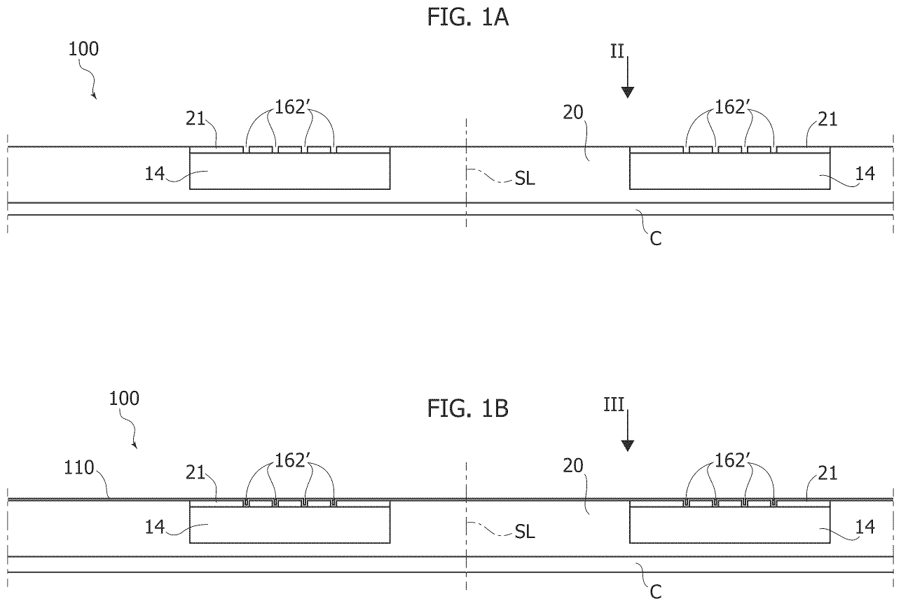

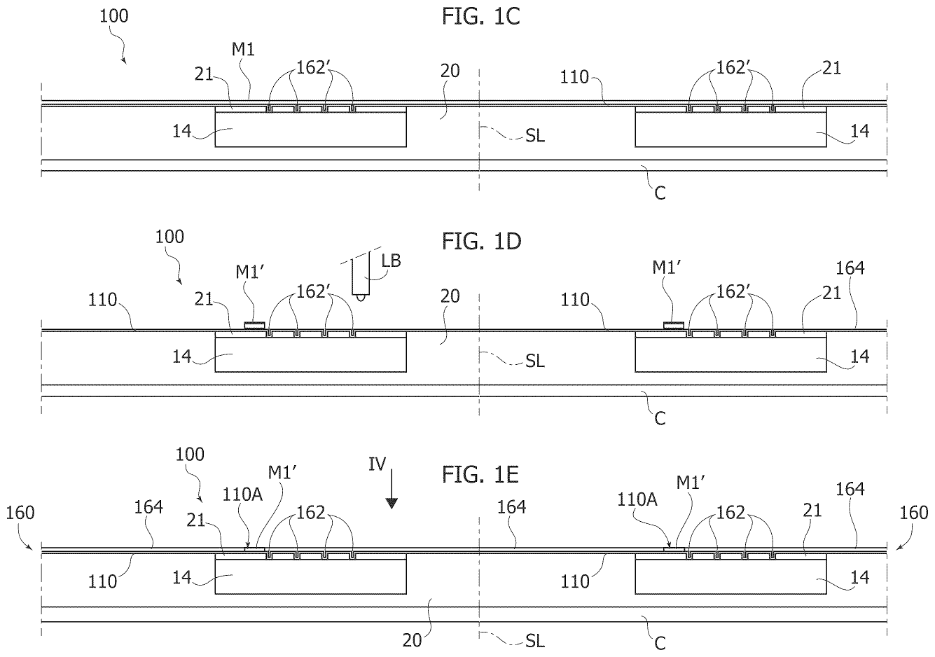

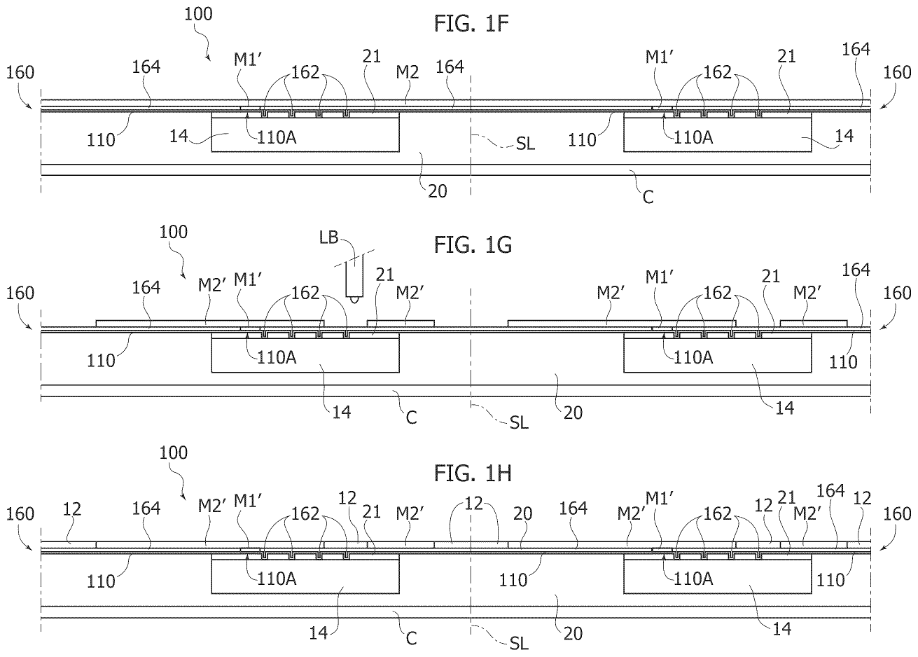

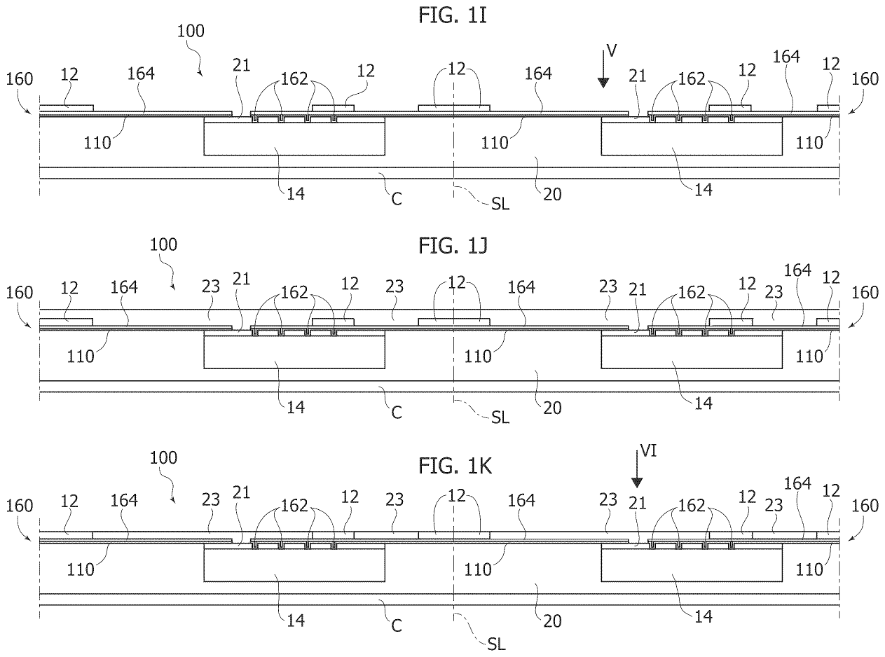

FIGS. 1A to 1K are cross-sectional views illustrative of a sequence of processing steps in manufacturing of semiconductor devices according to embodiments of the present description.

It will be appreciated that the sequence of steps of FIGS. 1A to 1K is merely exemplary insofar as: one or more steps illustrated in FIGS. 1A to 1K can be omitted, performed in a different manner (with other tools, for instance) and/or replaced by other steps; additional steps may be added; and one or more steps can be carried out in a sequence different from the sequence illustrated.

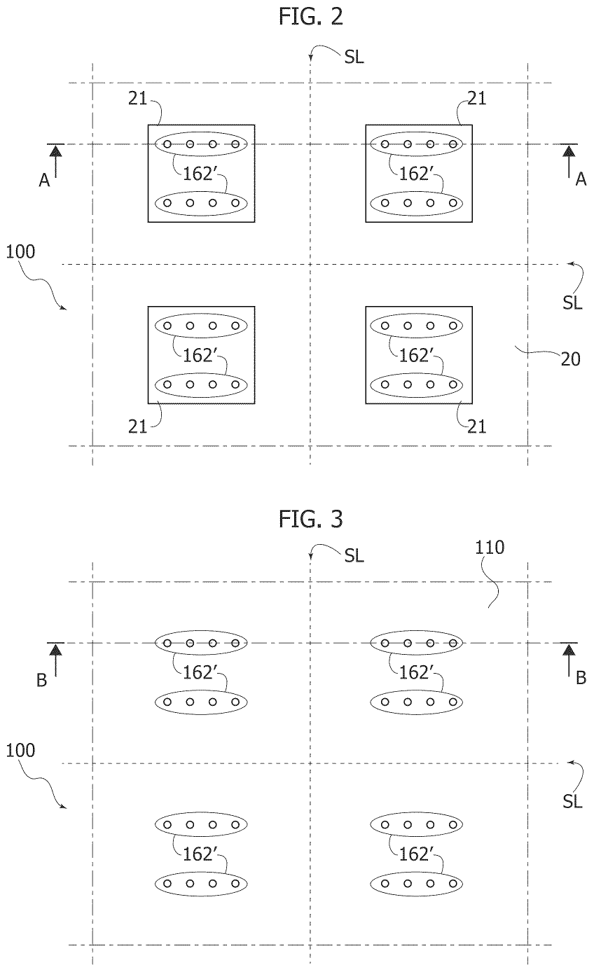

In describing the sequence of processing steps illustrated in FIGS. 1A to 1K, reference is made also to FIGS. 2 to 6. FIGS. 2 to 6 are plan views illustrative of details of a panel resulting from selected processing steps in the sequence illustrated in FIGS. 1A to 1K.

FIG. 1A is illustrative of a wafer or panel 100 arranged on a temporary (and possibly sacrificial) carrier C.

The panel or wafer 100 illustrated in FIG. 1A comprises a plurality of semiconductor dice or chips 14 (the terms chip/chips and die/dice are herein regarded as synonymous) embedded in an electrically insulating encapsulation 20, 21.

Hereinafter, reference will be made to a panel 100 being otherwise understood that a sequence of processing steps as described in relation to FIGS. 1A to 1K may be applied to both wafer level and/or panel level processing, irrespective of the particular shape and/or size of the wafer or panel.

Providing a panel 100 as illustrate in FIG. 1A may involve: providing a semiconductor (Si, SiC, GaN, for instance) wafer having embedded therein (in any way known in the art) a plurality of integrated circuits (ICs) which are not visible in the figures for simplicity; laminating an electrically insulating build-up film 21 (also referred to as mold film), such as an Ajinomoto Build-Up Film, at a surface of the semiconductor wafer (the active surface) for instance: opening (via laser ablation, for instance) vias 162′ towards the semiconductor dice 14 through the build-up film 21 to uncover corresponding die bonding pads (that is, electrical contacts, not visible in the figures for scale reasons) at the active surface of the semiconductor dice 14; singulating the semiconductor wafer into a plurality of individual (singulated) semiconductor dice 14, each semiconductor die 14 comprising at least one integrated circuit and a portion of the build-up film 21 laminated at the active surface thereof; arranging the plurality of individual (singulated) semiconductor dice 14 on a temporary carrier; and molding an electrically insulating molding material 20 (an epoxy resin, for instance) onto the plurality of individual semiconductor dice 14 arranged on the temporary carrier.

As illustrated in FIG. 1A, each semiconductor die 14 has a portion of the build-up film 21 (laminated prior to the singulation step, for instance) provided at the active surface of the semiconductor die 14, with vias 162′ opened through the build-up film 21 towards the die bonding pads of the semiconductor die 14.

The reference 162′ with an accent “′” is used to highlight the fact that proper, electrically conductive, vias (indicated with the reference 162 in FIG. 1E, for instance) will be formed in a subsequent processing step.

As illustrated in FIG. 1A, the portion of the (electrically insulating) build-up film 21 and the (electrically insulating) molding material 20 provide an electrically insulating encapsulation for the plurality of (IC) semiconductor dice 14.

Said otherwise, FIG. 1A is illustrative of a panel 100 of electrically insulating material 20, 21 encapsulating a plurality of semiconductor dice 14, the panel 100 having the plurality of semiconductor dice 14 embedded therein.

FIG. 2 is a plan view of a portion of a panel 100 as illustrated in FIG. 1A, seen in the viewing direction indicated by the arrow II in FIG. 1A (correspondingly, FIG. 1A is a cross-sectional view along line A-A of FIG. 2).

As illustrated in FIG. 2, a plurality of semiconductor dice 14 are embedded in the electrically insulating encapsulation 20, 21 with a portion of the build-up film 21 visible at the top/front surface of the panel 100.

The panel 100 is configured to be singulated into a plurality of panel portions by cutting along singulation lines SL in a (final) singulation step. Singulation lines SL are also visible in the cross-sectional view illustrated in FIG. 1A.

In embodiments as exemplified in the figures, each panel portion comprises one semiconductor die 14. In one or more embodiments, the panel 100 may be singulated (in a final singulation step) into panel portions that comprise two or more semiconductor dice.

That is, the panel 100 comprises a plurality of adjacent panel portions, wherein each panel portion comprises at least one semiconductor die 14 of the plurality of semiconductor dice 14 embedded in the panel 100.

In fact, as is conventional in manufacturing processes of semiconductor devices, plural devices may be concurrently processed (for instance, by processing a panel comprising a plurality of dice/devices) and subsequently singulated into individual devices in a final singulation step.

Providing a panel 100 as illustrated in FIGS. 1A and 2 is otherwise conventional in the art, which makes it unnecessary to provide a more detailed description herein.

The processing steps described with reference to FIGS. 1B to 1E are exemplary of processing steps to form a redistribution layer for the semiconductor dice 14 in the panel 100.

As known to those skilled in the art, a redistribution layer comprises a pattern of electrically conductive traces and vias that provides input/output (I/O) pads of an integrated circuit (that is, the die bonding pads provided at the active surface of the semiconductor dice 14) available in other locations.

FIG. 1B is illustrative of a seed layer 110 formed at the front/top surface of the panel 100, that is, at the front/top surface of the electrically insulating encapsulation 20, 21. The seed layer 110 may be formed via sputtering, for instance, of metallic material such as Ti and/or Cu material, for instance.

The seed layer 110 is also visible in FIG. 3, a plan view of a panel 100 as illustrated in FIG. 1B seen in the direction of view indicated by the arrow III in FIG. 1B (correspondingly, FIG. 1B is a cross-sectional view along line B-B of FIG. 3).

As illustrated in FIGS. 1B and 3, a seed layer 110 is formed over the whole top/front surface of the panel 100.

The seed layer 100 is also formed at the vias 162′ opened in the build-up film 21 in order to facilitate growing electrically conductive material (copper, for instance) to form proper, electrically conductive, vias to the semiconductor dice 14.

FIGS. 1C to 1E are illustrative of processing steps to provide a common redistribution layer (RDL) to the plurality of semiconductor dice 14 embedded in the panel 100.

Providing a common redistribution layer involves growing electrically conductive material (a metallic material such as copper, for instance) at selected locations (according to a desired redistribution pattern) of the front/top surface of the panel 100.

Electrically conductive vias and traces may be formed by growing, via electrolytic (or galvanic) plating, electrically conductive material onto selected regions of the seed layer 110 formed at the top/front surface of the panel 100.

In one or more embodiments, selectively growing electrically conductive material on the seed layer 110 may be facilitated by a patterned photoresist layer.

As illustrated in FIG. 1C, a first layer M1 of photoresist material is provided at the top/front surface of the panel 100. The first photoresist layer M1 may be provided as a laminated dry film, for instance.

The first photoresist layer M1 is subsequently patterned according to the desired redistribution pattern. Transferring a pattern to the first photoresist layer M1 may involve applying laser beam energy LB at selected portions of the first photoresist layer M1 provided at the top/front surface of the panel 100 and, subsequently, developing the first photoresist layer M1 to obtain a first patterned photoresist layer M1′, as illustrated in FIG. 1D.

In one or more embodiments, laser direct imaging (LDI) techniques may be used to transfer a desired pattern to the first photoresist layer M1.

The first patterned photoresist layer M1′ leaves uncovered selected regions of the top/front surface of the panel 100 (that is, the top/front surface of the electrically insulating encapsulation 20, 21) having the seed layer 110 formed thereon.

Said otherwise, a first photoresist layer M1 is provided over the whole top/front surface of the panel 100 (onto the seed layer 100 formed previously) and, subsequently, patterned (via LDI techniques, for instance) to provide the first patterned photoresist layer M1′. The first patterned photoresist layer M1′ has apertures at selected regions of the top/front surface of the panel 100 that leave uncovered the seed layer 110 formed thereon.

FIG. 1E is illustrative of electrically conductive material (copper, for instance) grown at the top/front surface of the panel 100 to form the common redistribution layer 160.

More in details, electrically conductive material is grown/deposited onto portions of the seed layer 110 that are left uncovered by the first patterned photoresist layer M1′.

As mentioned in the foregoing, electrically conductive material may be grown via an electrolytic plating step. In electrolytic (or galvanic) plating, an electric field between an anode and a workpiece, acting as a cathode, forces positively charged metal ions (of copper, for instance) to move to the cathode where they give up their charge and deposit as metal on the surface of the workpiece.

It is noted that the terms electrolytic plating, galvanic plating and electroplating are herein regarded as synonymous.

The seed layer 110, which covers the whole front/top surface of the panel 100, acts as a cathode in the electrolytic plating step, thus facilitating growing metallic material at the portions of the seed layer 110 left uncovered by the first patterned photoresist layer M1′.

As illustrated, the common redistribution layer 160 comprises: electrically conductive vias 162 extending through the electrically insulating encapsulation 20, 21, from the top/front surface of the panel 100 to the semiconductor dice 14; and electrically conductive traces/lines 164 extending at the front/top surface of the panel 100 starting from the vias 162 and electrically coupled thereto.

With reference to FIG. 1E, regions 110A of the seed layer 110 adjacent and complementary to the regions of seed layer 110 having electrically conductive material grown thereon are covered by the first patterned photoresist layer M1′.

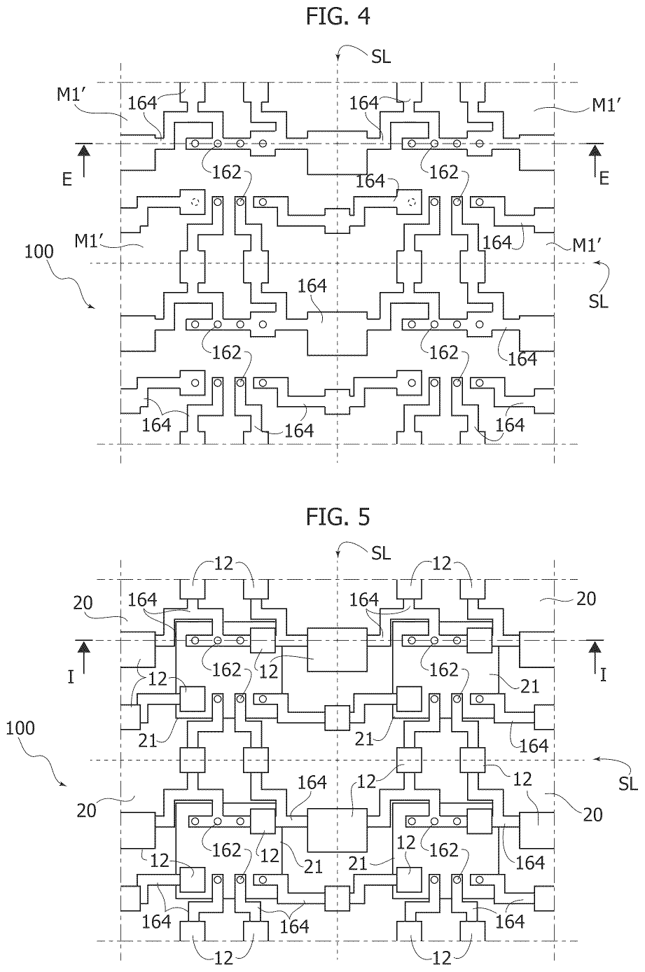

FIG. 4 is a plan view of a panel 100 as illustrated in FIG. 1E, seen in the viewing direction indicated by the arrow IV in FIG. 1E (correspondingly, FIG. 1E is a cross-sectional view along line E-E of FIG. 4).

As illustrated in FIG. 4, a common redistribution layer 160 is formed for the plurality of semiconductor dice 14 embedded in the panel 100 and comprises a corresponding plurality of RDL portions (at each panel portion defined by singulation lines SL) configured to provide an (individual) redistribution layer to each semiconductor die 14 in the panel 100.

As illustrated, the common redistribution layer 160 may comprise a pattern of electrically conductive formations (vias 162 and traces 164) that is repeated at each panel portion defined by the cutting/sawing lines SL.

It is noted that the particular pattern of the common redistribution layer 160 illustrated in FIG. 4 is merely exemplary and a common redistribution layer 160 according to any desired redistribution pattern may be formed via the processing steps described in the foregoing.

The first patterned photoresist layer M1′ covers regions of the seed layer 110A that (at least notionally) do not have electrically conductive material grown thereon that are adjacent and complementary to the regions of the seed layer 110 having electrically conductive material grown thereon (that is, vias 162 and traces 164 of the common redistribution layer 160).

The electrically conductive traces 164 and vias 162 in the common redistribution layer 160 are electrically coupled to each other via the portion 110A of the seed layer left at the surface of the panel 100.

Said otherwise, embodiments of the present description involve forming a redistribution layer 160 common to the plurality of semiconductor dice 14 embedded in the panel 100 by growing electrically conductive material (copper, for instance) onto first regions of the seed layer 110 formed at the surface of the panel 100.

The seed layer 110 comprises second regions 110A adjacent and complementary to the first regions of the seed layer 110 having electrically conductive material grown thereon.

As discussed in the following, the second regions 110A of the seed layer 110 facilitate keeping the common redistribution layer 160 at a desired plating potential, thus facilitating electroplating (that is, plating via an electrolytic plating step) solder material onto the common redistribution layer 160 to grow pads of solder material onto the common redistribution layer.

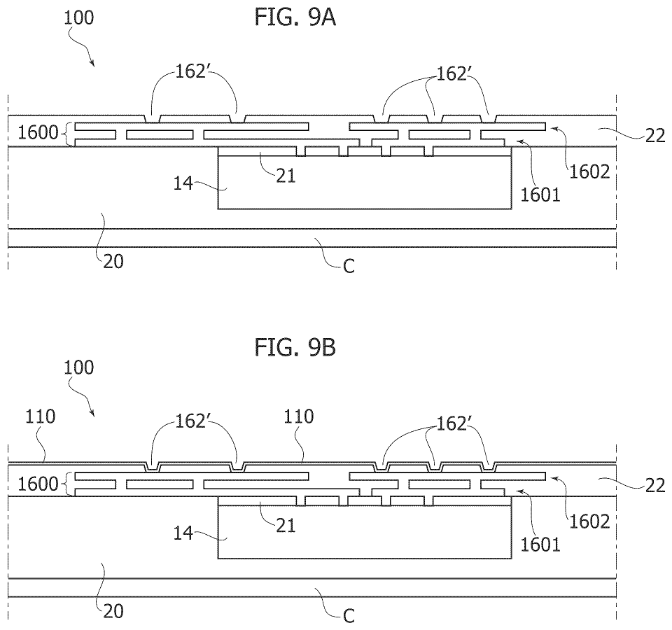

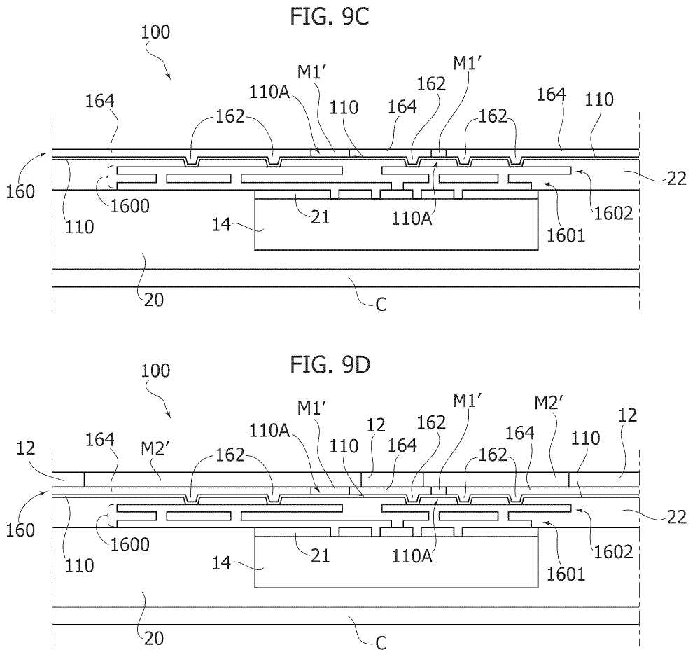

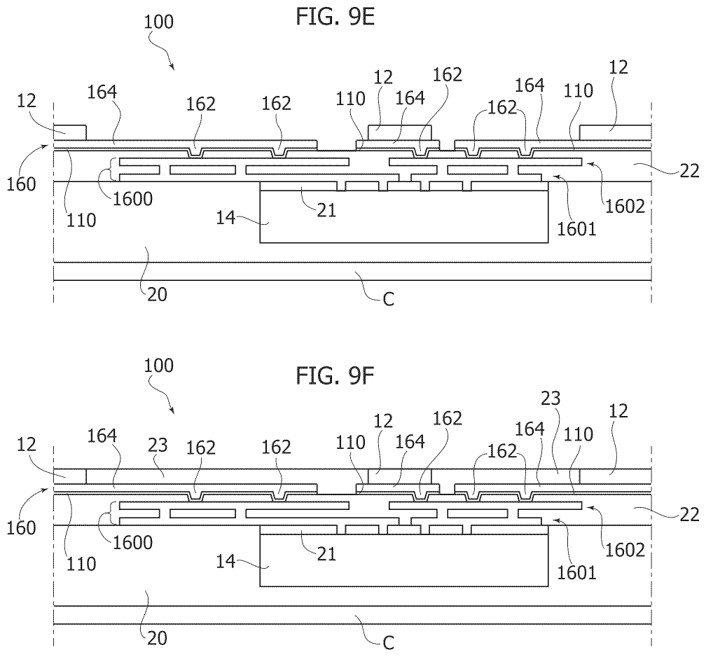

It is noted that the common redistribution layer 160 may also be formed with a multilayer structure. Embodiments of the present description may advantageously be applied also when devices provided with a multilayer redistribution layer are desired, as described with reference to FIGS. 9A to 9F.

FIGS. 1F to 1H are illustrative of processing steps to form pads 12 (also referred to as “studs”) of solderable material (tin or a tin alloy, for instance) for the plurality of devices comprised in the panel 100.

According to embodiments of the present description, solder material may be grown via electrolytic plating facilitated by the seed layer 110 kept (also at regions 110A) at the surface of the panel 100.

Similarly to what has been described in relation to FIGS. 1C and 1D, FIGS. 1F and 1G are illustrative of processing steps wherein: a second photoresist layer M2 is provided at the front/top surface of the panel 100 (a second dry film laminated thereon, for instance) having the common redistribution layer 160 formed thereon—illustrated in FIG. 1F; and the second photoresist layer M2 is patterned (again, via laser direct imaging LDI techniques, for instance) and developed to form a second patterned photoresist layer M2′—illustrated in FIG. 1G.

FIG. 1H is illustrative of solder material (tin or a tin alloy, for instance) grown at selected locations of the front/top surface of the panel 100 that are left uncovered by the second patterned photoresist layer M2′, to form therein pads 12 of solderable material.

In more detail, solder material is grown onto the metallic material of the common redistribution layer 160 formed previously.

A second electrolytic plating step is advantageously used to grow solder (and electrically conductive) material to form the solderable pads 12.

The electrolytic growth/deposition of solder material is facilitated by the seed layer 110 (acting as a cathode in the electrolytic plating step) that facilitates keeping the common redistribution layer 160 onto which solder material is grown at a common electric potential, thus facilitating establishing an electric field that forces ions of the solder material in the plating bath to deposit onto the electrically conductive material of the common redistribution layer 160.

The thickness T of the solderable pads 12 that can be grown via electrolytic plating is considerably larger than the thickness of a layer of solder material that may be plated via electroless plating; pads 12 having a thickness T of about 20 microns may be grown, for instance.

In one or more embodiments, pads 12 of solderable material are grown with a pad thickness T in the range between 10 and 200 microns, preferably in the range between 50 and 100 microns.

As discussed previously, electroless deposition of tin may result in (fairly) thinner layers of tin, having a thickness of about 3 to 5 microns, for instance.

Subsequently to growing solderable material to form the pads 12 of solder material, the second patterned photoresist layer M2′, the first patterned photoresist layer M1′ and the regions 110A of the seed layer 110 are removed.

Details of a panel 100 resulting from processing steps as described in the foregoing are illustrated in FIG. 1I. A plan view of a panel 100 as illustrated in FIG. 1I seen in the viewing direction indicated by the arrow V of FIG. 1 is illustrated in FIG. 5 (correspondingly, FIG. 1I is a cross-sectional view along line I-I of FIG. 5).

As illustrated in FIG. 5, the electrically insulating encapsulation 20, 21 is exposed at the surface of the panel 100 in response to the seed layer 110 being removed from the second regions 110A of the seed layer 110.

Advantageously, the panel 100 having the solderable pads 12 formed at the front/top surface thereof is processed via a baking step to facilitate forming an intermetallic region at the interface between the electrically conductive material (copper, for instance) of the common redistribution layer 160 and the solder material (tin, for instance) of the solderable pads 12.

For instance, in one or more embodiments the common redistribution layer 160 may be formed by growing copper material (via a first electrolytic plating step) and the solderable pads may be formed by growing tin material (via a second electrolytic plating step) via processing steps as described in the foregoing. In such embodiments, baking the panel 100 at a temperature of about 150° C. for one hour has been observed to give satisfactory results in terms of formation of an intermetallic region at the interface between the copper material of the common redistribution layer 160 and the tin material of the pads 12.

FIG. 1J is illustrative of a molding step where further molding material 23 (an epoxy resin, for instance) is molded onto the front/top surface of the panel 100 (having the common redistribution layer 160 as well as the pads 12 of solder material formed thereon) to form a further layer of electrically insulating encapsulation 23 thereon.

As illustrated, the further encapsulation material 23 covers the whole surface of the panel and, in particular, encapsulates the common redistribution layer 160 and the solderable pads 12.

Advantageously, the further molding material 23 is a molding material 23 with a molding temperature lower than the melting temperature of the solder material grown to form the solderable pads 12.

FIG. 1K is illustrative of a panel 100 resulting from partially removing (via grinding, for instance) the (further) encapsulation material 23 molded onto the panel 100 to expose a surface of the pads 12 of solder material. That is, the further encapsulation material 23 is partially removed starting from the top/front surface of the further encapsulation 23 to expose a surface of the pads 12 of solder material.

Said otherwise, FIGS. 1J and 1K are illustrative of processing steps to encapsulate the pads 12 of solder material as well as the common redistribution layer 160 in a further (electrically insulating) encapsulation 23, wherein the further encapsulation 23 has a surface opposite the surface of the panel 100, and wherein solder material of the pads 12 of solder material is exposed at the surface of the further encapsulation 23.

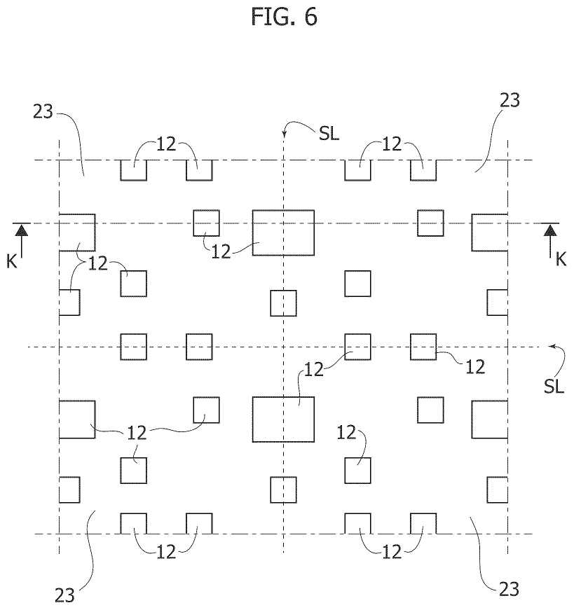

FIG. 6 is a plan view of a portion of a panel 100 as illustrated in FIG. 1K, seen in the viewing direction indicated by the arrow VI in FIG. 1K (correspondingly, FIG. 1K is a cross-sectional view along line K-K of FIG. 6).

As mentioned, a grinding step may be performed to expose a surface—the top/front surface in the figures—of the solderable pads 12 while keeping the common redistribution layer 160 encapsulated in the electrically insulating encapsulation material 23.

Subsequently, the panel 100 is singulated/partitioned into a plurality of (individual) panel portions wherein each panel portion provides a (finished) semiconductor device.

Singulating the panel 100 may be done via sawing, for instance, at singulation (sawing/cutting) lines SL indicated in FIGS. 1K and 6.

As visible in FIGS. 1K and 6, certain pads 12 of solder material may be located at the cutting lines SL. The person skilled in the art may appreciate that a side surface of these pads 12 is exposed at a side surface of the panel portion 10 in response to the singulation step. Said otherwise, pads 12 of solder material grown at the cutting lines SL result in pads 12 having solder material exposed at a side surface of the semiconductor device 10 obtained in response to singulating the panel 100 at the cutting lines SL.

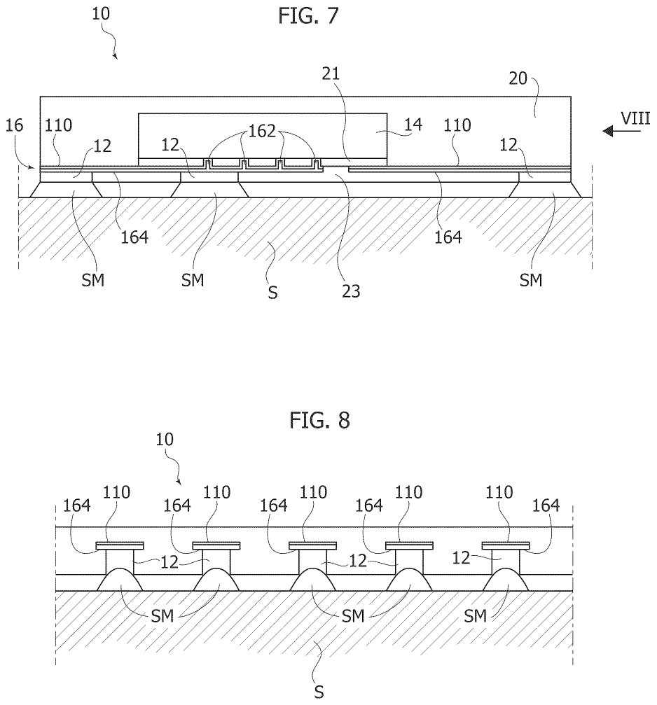

FIGS. 7 and 8 are, respectively, a cross-sectional view and a side view (wherein FIG. 8 is a side view of a device as illustrated in FIG. 7 seen in the direction of view indicated by the arrow VIII of FIG. 7) illustrative of a semiconductor device 10 obtainable via a method according to embodiments of the present description.

As mentioned, the semiconductor device 10 illustrated in FIGS. 7 and 8 is obtained by partitioning/singulating a panel 100 processed as described previously.

That is, a semiconductor device 10 is provided by a singulated portion of a panel 100 as described in the foregoing, wherein the device 10 comprises: one (or more) semiconductor die 14 embedded in a portion of the panel 100 of electrically insulating molding material 20; a portion 16 of the common redistribution layer 160 formed at a surface of the portion of the panel 100; and pads 12 of solder material grown onto the portion 16 of the common redistribution layer 160.

The pads 12 of solder material are electrically coupled to the semiconductor die 14 embedded in the portion of the panel 100 via the portion 16 of the common redistribution layer 160. Said otherwise, the portion 16 of the common redistribution layer 160 provides a (individual) redistribution layer 16 to the semiconductor die 14 of the device 10.

The semiconductor device 10 illustrated in FIGS. 7 and 8 is mounted on a (final) supporting substrate S (a printed circuit board (PCB) for instance). As illustrated, (further) solder material SM may be provided at the pads 12 of solder material to facilitate forming the electrical coupling between the pads 12 and the supporting substrate S.

With reference to FIG. 8, the semiconductor device 10 may have pads 12 of solder material having a side surface thereof exposed at a side surface of the device 10. The solder material exposed at the side of the device provides wettable flanks that facilitate forming a solder fillet SM at the sides of the device 10. As discussed in the foregoing, such wettable flanks result from pads 12 of solder material that were located at the cutting lines SL of the panel 100.

As mentioned, the redistribution layer 160 may also have a multilayer structure. FIGS. 9A to 9F are cross-sectional views illustrative of processing steps according to embodiments of the present description to obtain a semiconductor device provided with a multilayer redistribution layer.

FIG. 9A is illustrative of a portion of a panel 100 comprising an electrically insulating encapsulation 20, 21, 22 having embedded therein a plurality of semiconductor dice 14 as well as electrically conductive formations 1600 for the semiconductor dice 14.

A panel as exemplified in FIG. 9A may be obtained starting from a panel 100 as illustrated in FIG. 1A (for which a description is not repeated herein) by providing electrically conductive formations 1600 embedded in electrically insulating material 22.

As discussed in the following, the electrically conductive formations 1600 provide first N−1 layers of a N-layers redistribution layer for the (final) semiconductor device. Providing the electrically conductive formations 1600 embedded in the electrically insulating material 22 involves per se conventional processing steps.

For each (patterned) layer of electrically conductive formations (such as the layers 1601 and 1602 illustrated in FIG. 9A) this may involve: growing a patterned layer 1601, 1602 of electrically conductive formations (traces and vias), facilitated by a patterned photoresist layer as discussed in the foregoing, for instance; laminating an electrically insulating build-up (or mold) film onto the first patterned layer 1601, 1602 of electrically conductive formations to embed the electrically conductive formations in the in the build-up film; and opening (via laser ablation, for instance) vias through the build-up film towards the electrically conductive formations embedded therein.

Such processing steps, per se conventional in the art, may be repeated for each layer of the N−1 layers that is desired to provide.

With reference to FIG. 9A, processing as described in the foregoing results in a plurality of electrically conductive layers 1601, 1602 embedded in a plurality of electrically insulating build-up films.

It is noted that in FIG. 9A individual build-up films are not visible for simplicity; an electrically insulating encapsulation 22 resulting from the stacking of the build-up films is illustrated, with electrically conductive formations 1600 embedded therein.

Said otherwise, the processing steps described in the foregoing result in a panel 100 having the plurality of semiconductor dice 14 and the electrically conductive formations 1600 embedded therein, wherein the panel 100 is formed by encapsulating the plurality of semiconductor dice 14 as well as electrically conductive formations 1600 therefor in an electrically insulating encapsulation (comprising the molding material 20, the build-up films 21, 22).

The electrically conductive formations 1600 provide electrical coupling points for the plurality of semiconductor dice 14 embedded in the panel.

Further processing of a panel 100 as illustrated in FIG. 9A involve similar processing steps as described in relation to FIGS. 1A to 1K (and FIGS. 2 to 6).

A seed layer 110 of seed material (a TiCu seed layer, for instance) is formed (via sputtering, for instance) at the (top/front) surface of the panel 100, as illustrated in FIG. 9B.

FIG. 9C is illustrative of a processing step wherein an electrically conductive redistribution layer 160 common to the plurality of semiconductor dice 14 embedded in the panel 100 is formed by growing electrically conductive material onto first regions of the seed layer 110 (at apertures formed in a first patterned photoresist layer M1′, for instance) formed at the surface of the panel 100.

As illustrated, the common redistribution layer 160 comprises: electrically conductive vias 162 extending through the electrically insulating encapsulation 22, from the top/front surface of the panel 100 to the electrically conductive formations 1600 (that is, the first N−1 layer of a multilayer RDL); and electrically conductive traces/lines 164 extending at the front/top surface of the panel 100 starting from the vias 162 and electrically coupled thereto.

As illustrated, the common redistribution layer 160 is electrically coupled to the plurality of semiconductor dice 14 embedded in the panel 100 via the electrically conductive formations 1600 encapsulated in the electrically insulating encapsulation 22.

Subsequently, as illustrated in FIG. 9D, pads 12 of solder material are grown onto the common redistribution layer 160 (at apertures of a second patterned photoresist layer M2′, for instance), wherein the pads 12 of solder material are electrically coupled to semiconductor dice 14 in the plurality of semiconductor dice 14 via the common redistribution layer 160 (and the electrically conductive formations 1600 embedded in the panel 100).

FIG. 9E is illustrative of a processing step comprising removing the seed material at second regions 110A of the seed layer 110 adjacent and complementary to the first regions of the seed layer 110 having electrically conductive material grown thereon.

Similarly to what has been described in the foregoing, growing pads 12 of solder material onto said common redistribution layer 160 comprises electrolytically growing solder material onto the common redistribution layer 160 kept at a desired plating electric potential via the second regions 110A of the seed layer 110.

As illustrated in FIG. 9F, in one or more embodiments the pads 12 of solder material as well as the common redistribution layer 160 may be encapsulated in a further encapsulation 23 of electrically insulating material.

The further encapsulation 23 has a surface opposite said surface of the panel 100, and solder material of said pads 12 of solder material may be exposed at the (top/front) surface of the further encapsulation 23.

In summary, solutions as described herein involve encapsulating a plurality of semiconductor dice 14 in an electrically insulating encapsulation 20, 21, 22 to form a panel 100 having the plurality of semiconductor dice 14 embedded therein.

A seed layer 110 of seed material (a TiCu seed layer, for instance) is subsequently formed at a surface of the panel 100.

A common redistribution layer 160 to the plurality of semiconductor dice 14 embedded in the panel 100 is formed by growing electrically conductive material onto first regions of the seed layer 110 formed at the surface of the panel 100. The seed layer 110 comprises second regions 110A adjacent and complementary to the first regions of the seed layer 110 having electrically conductive material grown thereon.

Pads 12 of solder material are grown onto the common redistribution layer 16. The pads 12 of solder material are electrically coupled to semiconductor dice 14 in the plurality of semiconductor dice 14 via the common redistribution layer 160.

Growing the pads 21 of solder material onto the common redistribution layer 160 comprises: keeping the common redistribution layer 160 at a plating potential via the second regions 110A of the seed layer 110; and electroplating solder material onto the common redistribution layer 160 kept at a plating potential via the second regions 110A of the seed layer 110.

The seed material is subsequently removed at the second regions 110A of the seed layer 110.

In one or more embodiments, the panel 100 having the pads 12 of solder material grown onto the common redistribution layer 160 is baked to facilitate forming an intermetallic region at the interface between the electrically conductive material (copper, for instance) of the common redistribution layer 160 and the solder material (tin or a tin alloy, for instance) of the pads 12 grown thereon.

In one or more embodiments, the pads 12 of solder material and the common redistribution layer 160 are embedded in an encapsulation of further electrically insulating molding material 22. The further electrically insulating molding material 22 is partially removed (via grinding, for instance) starting from the top/front surface of the encapsulation to expose a surface of the pads 12 of solder material (that is, the surface of the pads 12 that is configured to be soldered to a final supporting substrate S such as a PCB, for instance).

Said otherwise, one or more embodiments comprise encapsulating the pads 12 of solder material as well as the common redistribution layer 160 in an encapsulation 22 of further electrically insulating molding material having a surface opposite said surface of the panel 100, with solder material of the pads 12 of solder material is exposed at said surface of the encapsulation 22.

In one or more embodiments, the panel 100 is singulated into a plurality of semiconductor devices 10, where each semiconductor device 10 in the plurality of semiconductor devices 10 comprises: at least one semiconductor die 14 embedded in a portion of the panel 100 of electrically insulating molding material 20; a portion 16 of the common redistribution layer 160 formed at the surface of the portion of the panel 10; and pads 12 of solder material (electrolytically) grown onto the portion 16 of the common redistribution layer 160, where the pads 12 of solder material are electrically coupled to the at least one semiconductor die 14 via the portion 16 of the common redistribution layer 160 (or, said otherwise, the portion 16 of the common redistribution layer provides a redistribution layer to the—individual, singulated—semiconductor device 10).

In one or more embodiments, the panel 100 is singulated at cutting lines SL; solder material of the pads 12 of solder material grown at the cutting lines SL is exposed at a side surface of the semiconductor device 10 in response to the singulating along the cutting lines SL.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
encapsulating a plurality of semiconductor dice in an electrically insulating encapsulation to form a panel having the plurality of semiconductor dice embedded therein;
forming a seed layer of seed material at a surface of said panel;
growing electrically conductive material onto first regions of the seed layer formed at the surface of the panel to form an electrically conductive redistribution layer common to the plurality of semiconductor dice embedded in the panel, wherein the seed layer further comprises second regions, adjacent and complementary to said first regions, that do not have electrically conductive material for the electrically conductive redistribution layer thereon;
growing pads of solder material onto said electrically conductive redistribution layer, wherein the pads of solder material are electrically coupled to semiconductor dice in the plurality of semiconductor dice via the electrically conductive redistribution layer; and
removing the seed material at said second regions of the seed layer;
wherein growing pads of solder material onto said electrically conductive redistribution layer comprises:
keeping the electrically conductive redistribution layer at a plating electric potential via said second regions of the seed layer; and
electrolytically growing solder material onto the electrically conductive redistribution layer kept at the plating electric potential via said second regions of the seed layer.

2. The method of claim 1, further comprising encapsulating the plurality of semiconductor dice and electrically conductive formations at each of the semiconductor dice in the electrically insulating encapsulation to form the panel, wherein the electrically conductive redistribution layer common to the plurality of semiconductor dice embedded in the panel is electrically coupled to the plurality of semiconductor dice via said electrically conductive formations.

3. The method of claim 1, wherein the pads of solder material have a pad thickness in a range between 10 and 200 microns.

4. The method of claim 1, wherein:
said electrically conductive material comprises copper; and
said solder material comprises tin or a tin alloy.

5. The method of claim 1, further comprising baking the panel at a temperature sufficient to form an intermetallic region at an interface between the electrically conductive material of the electrically conductive redistribution layer and the solder material of the pads.

6. A semiconductor product produced by the method of claim 5.

7. The method of claim 1, wherein growing electrically conductive material onto first regions of the seed layer comprises electrolytically growing electrically conductive material onto said first regions of the seed layer.

8. The method of claim 1, further comprising encapsulating the pads of solder material and the electrically conductive redistribution layer in a further encapsulation of electrically insulating material, wherein the further encapsulation has a surface opposite said surface of the panel, and wherein solder material of the pads of solder material is exposed at said surface of the further encapsulation.

9. A semiconductor product produced by the method of claim 8.

10. The method of claim 1, further comprising singulating the panel into a plurality of semiconductor devices, wherein each semiconductor device in the plurality of semiconductor devices comprises:
at least one semiconductor die embedded in a portion of the panel of electrically insulating molding material;
a portion of the electrically conductive redistribution layer formed at the surface of the portion of the panel; and
pads of solder material grown onto said portion of the electrically conductive redistribution layer, wherein the pads of solder material are electrically coupled to the at least one semiconductor die via said portion of the electrically conductive redistribution layer.

11. A semiconductor product produced by the method of claim 10.

12. The method of claim 10, wherein singulating is performed at cutting lines, wherein pads of solder material grown at the cutting lines have solder material exposed at a side surface of the semiconductor devices in response to said singulating the panel at the cutting lines.

13. A semiconductor product produced by the method of claim 12.
